(19) United States
(12) Patent Application Publication
(10) Pub. No.: US 2024/0141493 A1
(43) Pub. Date: May 2, 2024

(54) SINGLE PIECE OR TWO PIECE SUSCEPTOR

(71) Applicant: Applied Materials, Inc., Santa Clara, CA (US)

(72) Inventors: Vishwas Kumar PANDEY, Madhya Pradesh (IN); Ala MORADIAN, Sunnyvale, CA (US); Lori D. WASHINGTON, San Jose, CA (US); Shu-Kwan LAU, Sunnyvale, CA (US)

(21) Appl. No.: 18/223,183

(22) Filed: Jul. 18, 2023

(30) Foreign Application Priority Data
Oct. 27, 2022 (IN) 202241061170

(51) Int. Cl. C23C 16/458; C23C 16/46

(52) U.S. Cl. CPC C23C 16/4581; C23C 16/46

(57) ABSTRACT

In one embodiment, a processing chamber, suitable for use in semiconductor processing, includes a chamber body enclosing an interior volume. A susceptor is disposed in the interior volume, and the interior volume includes a purge interior volume below the susceptor and a process volume above the substrate support. A liner is disposed radially outward of the susceptor. The processing chamber also includes a preheat ring. The preheat ring is configured to engage the susceptor when the susceptor is an elevated processing position and to engage the liner when the susceptor is in a lowered loading/unloading position.

### CROSS-REFERENCE TO RELATED APPLICATIONS

This application claims priority to Indian Provisional Patent Application Serial No. 202241061170, filed on Oct. 27, 2022, which is herein incorporated by reference.

### BACKGROUND

Embodiments of the present disclosure generally relate to methods of and apparatus for improved gas flow in processing chambers, such as those used in semiconductor manufacturing.

### DESCRIPTION OF THE RELATED ART

Purge gas is often provided below a substrate support in a processing chamber to prevent process gases from entering the volume in the processing chamber below the substrate support. When process gases enter the volume below the substrate support problems can occur, such as unintended depositions on and/or corrosion of surfaces below the substrate support, such as deposition on the backside of the substrate support. These unintended depositions and/or corrosions increase the frequency for when the chamber needs to be cleaned or maintained (e.g., with replacement parts). Furthermore, unintended depositions on the backside of the substrate support can reduce the uniformity of the process being performed on a substrate that is positioned on the substrate support. For example, depositions on the backside of the substrate support can reduce the uniformity (e.g., thickness uniformity) of a deposition being performed.

Generally, a flowrate of purge gas can be increased to reduce the problems associated with process gases entering the volume below the substrate support, such as backside deposition on the substrate support. However, increasing a flowrate of purge gas increases center-to-edge non-uniformity of a film being formed on a substrate, and involves gas expenditures and inefficiencies.

Accordingly, there is a need for improved processing chamber equipment and methods of using the same.

### SUMMARY

In one embodiment, a processing chamber, suitable for use in semiconductor processing, includes a chamber body enclosing an interior volume. A susceptor is disposed in the interior volume, and the interior volume includes a purge interior volume below the susceptor and a process volume above the susceptor. A liner is disposed radially outward of the susceptor. The processing chamber also includes a preheat ring. The preheat ring is configured to engage the susceptor when the susceptor is an elevated processing position and to engage the liner when the susceptor is in a lowered loading/unloading position.

In another embodiment, a method of processing a substrate includes positioning a substrate on a susceptor within a processing chamber, and vertically actuating the susceptor into contact with a preheat ring to disengage the preheat ring from a liner. The method also includes performing a deposition process on the substrate while the preheat ring is in contact with the susceptor, and lowering the susceptor with the substrate thereon into a loading/unloading position, the lowering including engaging the liner with the preheat ring.

In another embodiment, a processing chamber, suitable for use in semiconductor processing, comprises a chamber body enclosing an interior volume. A susceptor is disposed in the interior volume, and the interior volume includes a purge volume below the susceptor and a process volume above the susceptor. The susceptor includes a single pocket formed therein for supporting one substrate. The susceptor has an outer diameter that is at least 75% greater than the outer diameter of the pocket. The processing chamber also includes a liner disposed radially outward of the susceptor.

In another embodiment, a method of processing a substrate includes positioning a substrate on a susceptor within a processing chamber, and susceptor including an integral or affixed preheat ring. The susceptor is radially spaced from a liner of the processing chamber. The method also includes performing a deposition process on the substrate while the substrate is positioned on the susceptor, and lowering the susceptor with the substrate thereon into a loading/unloading position. The susceptor does not engage the liner with the integrally-formed or affixed preheat ring during the lowering.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross-sectional view of a processing chamber according to one embodiment.

FIGS. 2A and 2B are schematic partial illustrations of a processing chamber configuration, according to one embodiment.

FIGS. 2C and 2D are schematic partial illustrations of a processing chamber configuration, according to another embodiment.

FIG. 2E is schematic sectional perspective view of a preheat ring and a susceptor, according to one embodiment.

FIGS. 3A and 3B are schematic partial illustrations of a processing chamber configuration, according to another embodiment.

FIGS. 4A and 4B are schematic partial illustrations of a processing chamber configuration, according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to equipment that improves purge gas flow within a processing chamber, and methods of using the same.

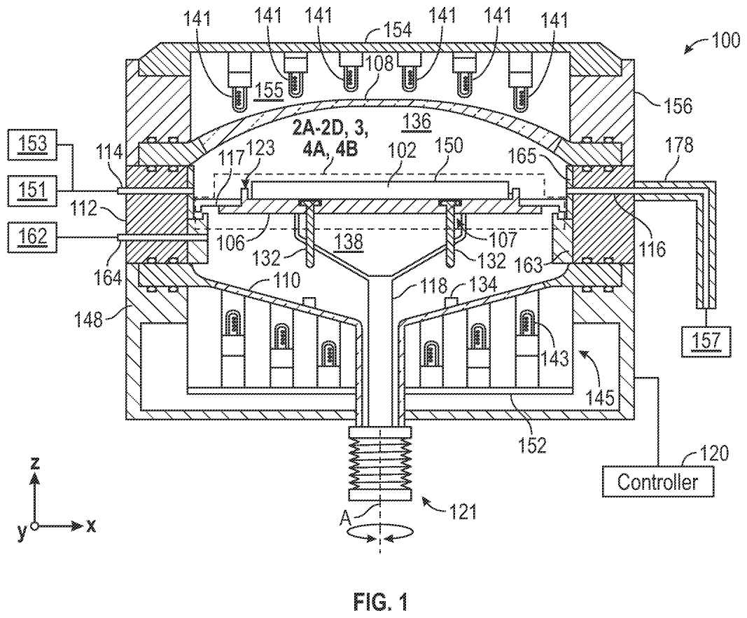

FIG. 1 is a schematic side cross-sectional view of a processing chamber 100, according to one implementation. The processing chamber 100 is a deposition chamber. In one embodiment, which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a susceptor 106 (e.g., a substrate support), an upper window 108 (such as an upper dome), a lower window 110 (such as a lower dome), a plurality of upper lamps 141, and a plurality of lower lamps 143. As shown, a controller 120 is in communication with the processing chamber 100 and is used to control processes and methods, such as the operations of the methods described herein.

The susceptor 106 is disposed between the upper window 108 and the lower window 110. The susceptor 106 includes a support face 123 that supports the substrate 102. The plurality of upper lamps 141 are disposed between the upper window 108 and a lid 154. The plurality of upper lamps 141 form a portion of the upper lamp module 155. The lid 154 may include a plurality of sensors (not shown) disposed therein for measuring the temperature within the processing chamber 100. The plurality of lower lamps 143 are disposed between the lower window 110 and a floor 152. The plurality of lower lamps 143 form a portion of a lower lamp module 145. The upper window 108 is an upper dome and is formed of an energy transmissive material, such as quartz. The lower window 110 is a lower dome and is formed of an energy transmissive material, such as quartz.

A process volume 136 and a purge volume 138 are formed between the upper window 108 and the lower window 110. The process volume 136 and the purge volume 138 are part of an internal volume defined at least partially by the upper window 108, the lower window 110, and the one or more liners 163, 165. The process volume 136 and the purge volume 138 are separated by the susceptor 106.

The internal volume has the susceptor 106 disposed therein. The susceptor 106 includes a top surface on which the substrate 102 is disposed. The susceptor is formed from a material, such as silicon carbide, graphite, black quartz, or silicon-carbide coated graphite to facilitate heating of the substrate 102 in combination with upper lamps 141 and the lower lamps 143. The susceptor 106 is attached to a shaft 118. The shaft 118 is connected to a motion assembly 121. The motion assembly 121 includes one or more actuators and/or adjustment devices that provide movement and/or adjustment for the shaft 118 and/or the s susceptor 106 within the processing volume 136. The motion assembly 121 moves the shaft 118 and susceptor 106 between a process position (shown in FIG. 1) and substrate loading/unloading position vertically beneath the process position. In the loading/unloading position, substrates, such as wafer, may be loaded onto or removed from the susceptor 106 with the assistance of lift pins 132.

The susceptor 106 includes lift pin holes 107 disposed therein. The lift pin holes 107 are sized to accommodate the lift pins 132 for lifting of the substrate 102 from the susceptor 106 either before or after a deposition process is performed. The lift pins 132 may rest on lift pin stops 134 when the susceptor 106 is lowered from a process position to a transfer position.

The flow module 112 includes a plurality of gas inlets 114, a plurality of purge gas inlets 164, and one or more gas exhaust outlets 116. The plurality of gas inlets 114 and the plurality of purge gas inlets 164 are disposed on the opposite side of the flow module 112 from the one or more gas exhaust outlets 116. A preheat ring 117 is disposed radially inward of an upper liner 165. The upper liner 165 and a lower liner 163 are coupled to an inner surface of the flow module 112. The pre-heat ring 117 facilitates heating of the process gases as the process gases pass thereover. The heating of the process gases facilitates uniform deposition on the substrate 102. The preheat ring 117 is formed from silicon carbide, graphite, black quartz, or silicon-carbide coated graphite, and may be heated by upper lamps 141 and/or lower lamps 143. The upper liner 165 is disposed vertically above the lower liner 163. As discussed below, the preheat ring 117 can be disposed at least partially above the lower liner 163. The lower liner 163 and upper liner 165 are disposed on an inner surface of the flow module 112 and protect the flow module 112 from reactive gases used during deposition operations and/or cleaning operations. The present disclosure contemplates that one or more additional liners (in addition to the upper liner 165) can be used above and/or below the lower liner 163. The present disclosure contemplates that the upper liner 165 or the lower liner 163 can be omitted, or the upper liner 165 and the lower liner 163 can be integrally formed as a single liner. In one or more examples, the preheat ring 117 may be spaced laterally (e.g., in the X-direction) from the upper liner 165 from about 0.25 mm to about 12 mm, such as from about 0.5 mm to about 6.5 mm. Other dimensions are also contemplated.

The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one embodiment, which can be combined with other embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

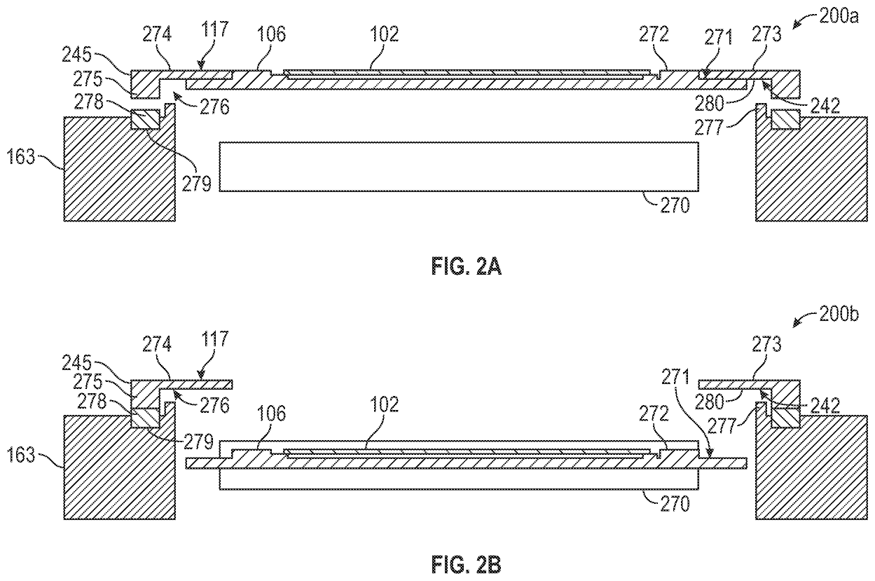

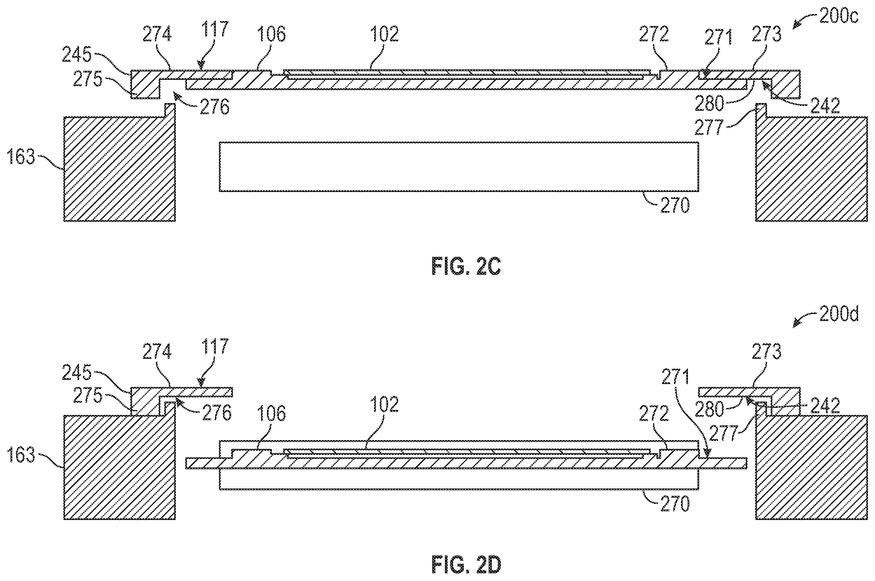

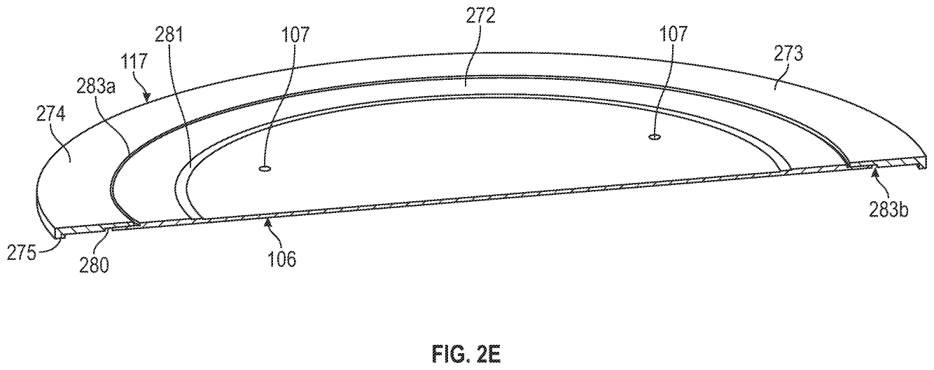

FIGS. 2A and 2B are schematic partial illustrations of a processing chamber configuration 200a, for example the processing chamber 100 of FIG. 1, according to one embodiment. In particular, FIG. 2A illustrates the lower liner 163, the preheat ring 117, and the susceptor 106 having a substrate 102 therein, in a processing position (e.g., aligned with or immediately below slit valve tunnel 270. FIG. 2B illustrates the same components in a loading/unloading position. FIG. 2E is schematic sectional perspective view of a preheat ring 117 and a susceptor 106.

In the processing position shown in FIG. 2A, the susceptor 106 supports the preheat ring 117 at an outer edge of the susceptor 106. The susceptor 106 supports the preheat ring 117 at a mating interface 280, which may be corresponding planar surfaces of the preheat ring 117 and the susceptor 106. It is contemplated that the mating interface 280 may also include alignment features, such as male/female protrusions, to facilitate alignment and/or securing of the preheat ring 117 relative to the susceptor 106.

As the susceptor 106 rotates during processing, so too does the preheat ring 117 and the substrate 102 supported thereon. In such an example, the susceptor 106 includes an outward stepped surface 271 with which the preheat ring 117 interfaces to facilitate support and alignment of the preheat ring 117. In one or more embodiments, the outward stepped surface 271 of the susceptor 106 supports an inward stepped surface 242 of the preheat ring 117. The upper surface 272 of the susceptor 106 and an upper surface 273 of the preheat ring 117 are coplanar to facilitate uniform gas flow therefore and uniform deposition during processing. The substrate 102 may also have an upper surface that is coplanar (or substantially coplanar) with the upper surfaces 272 and 273. The substrate 102 is supported on a support ledge 281 above a pocket 282 (See FIG. 2E). The support ledge 281 spaces the substrate 102 from the bottom of the pocket 282, reducing the contact area between the substrate 102 and the susceptor 106. The reduced contact between the substrate 102 and the susceptor 106 facilitates improved thermal uniformity of the substrate 102 during processing, thus facilitating improved deposition uniformity. The vertical position of the support ledge 281 may be selected to position the top of the substrate 102 relative to the upper surface 272 of the susceptor 106 and the upper surface 273 of the preheat ring 117. It is contemplated that one or more channels 283a, 283b may be formed at the laterally-spaced interfaces of the preheat ring 117 and the susceptor 106 to accommodate engagement between the preheat ring 117 and the susceptor 106. It is contemplated, however, that channels 283a, 283b may be omitted.

The preheat ring 117 is a ring-shaped member having a horizontal (e.g., planar) member 274 and circular vertical extension 275 disposed on a lower surface of the horizontal member 274. As illustrated, the horizontal member 274 and the circular vertical extension 275 have the same outer diameter, but the horizontal member 274 has a smaller internal diameter than the circular vertical extension 275. Other configurations are also contemplated. The relatively larger internal diameter of the circular vertical extension 275 forms a gap 276 between the circular vertical extension 275 and an outer edge of the susceptor 106 when the susceptor 106 supports the preheat ring 117 thereon. The gap 276 facilitates engagement of the preheat ring 117 with the lower liner 163, while allowing the susceptor 106 to vertically actuate without engaging the lower liner 163. Thus, the susceptor can be vertically actuated (e.g., lowered) to disengage the preheat ring 117 from the susceptor 106.

FIG. 2B illustrates the susceptor 106 in the loading/unloading position. Vertical lowering of the susceptor 106 positions the preheat ring 117 into contact with the lower liner 163. The preheat ring 117 remains disposed on the lower liner 163 as the susceptor continues into the loading/unloading position, adjacent slit valve tunnel 270, so that substrates 102 may be transferred to and from the susceptor 106. To facilitate transfer of the preheat ring 117 to the lower liner 163, the lower liner 117 includes a vertical extension 277 at the radially-inward edge of the lower liner 163. The vertical extension 277 may be a ring, and engages the gap 276 as the susceptor 106 is lowered. As the susceptor 106 continues downward, the vertical extension 277 contacts an underside of the preheat ring 117. For example, the vertical extension 277 contacts a bottom surface of the horizontal member 274. Since the circular vertical member 275 has an inner diameter greater than the outer diameter of the vertical extension 277, the vertical extension facilitates both securing of the preheat ring 117, and alignment of the preheat ring 117, on the lower liner 163.

The lower liner 163 is generally formed from quartz, although other materials are contemplated. To reduce thermal shock to the preheat ring 117 as the preheat ring 117 engages (e.g., contacts) the lower liner 163, an insert 278 is disposed within a pocket 279 formed in the upper surface of the lower liner 163. In one example, the insert 279 is positioned radially outward of, and lower than, the vertical extension 277. The insert 279 may be a ring, or may include multiple components positioned at predetermined increments in a generally circular configuration. The insert is formed of a material that is the same as the preheat ring 117, or that has a similar property or properties to the preheat ring 117. For example, the similar property or property may include a similar heat transfer coefficient. Thus, as preheating ring 117 engages and disengages the lower liner 163, thermal shock to the preheat ring 117 is reduced, thus reducing stress to the preheat ring 117 and the likelihood of breakage of the preheat ring 117.

The circular vertical extension 275 of the preheat ring 117 is disposed outwardly of the vertical extension 277 of the lower liner 163. The insert 278 is disposed below the circular vertical extension 275 of the preheat ring 117 and outwardly of the vertical extension 277 of the lower liner 163.

By positioning the preheat ring 117 on the susceptor 106 during processing, process gas flow within a processing chamber is improved, thus improving deposition uniformity and reducing deposition in undesired locations of the processing chamber. For example, with the preheat ring 117 resting on the susceptor 106, gaps which allow gas to flow therebetween are eliminated. Thus, process gas cannot flow between the preheat ring 117 and the susceptor 106 into a lower region of the chamber, such as the purge volume 138. Thus, the likelihood of deposition into the purge volume 138 and/or corrosion of components interfacing the purge volume 138 is reduced or eliminated. The reduction in undesired deposition in the purge volume 138 extends the time between chamber cleanings (thus increasing throughput) and improves process uniformity since chamber components in the purge volume have less unintended deposition thereon (e.g., optical transmission of through the lower window 110 remains unimpeded, improving process control). The reduction in corrosion extends the time between chamber cleanings and/or increases operational lifespans of chamber components.

In addition, positioning the preheat ring 117 on the susceptor 106 during deposition processing improves film uniformity by improving center-to-edge deposition consistency. In other designs, the outer edge of the substrate is positioned relatively close to the outer edge of a susceptor. The movement of gases near the edge of the susceptor correspondingly affects gas flow near the edge of the substrate, resulting in affected deposition near the edge of the substrate relative to the center of the substrate. For example, in other designs, the movement of purge gas or process gas through a gap between the preheat ring and the susceptor affects the cross flow of process gases as the processes gases travel over the substrate. These affects result in unintended turbulence or other gas flow inconsistencies, affect film deposition uniformity. However, the preheat ring 117 and the susceptor 106 of the present disclosure substantially reduce or eliminates these adverse effects.

In addition, in other designs, as the susceptor rotates during processing, the susceptor can “drag” process gases at a perimeter of the susceptor. The “dragging” of process gases affects process gas flow uniformity near the edge of the susceptor, and consequently, also near the edge of the substrate. The changes in process gas flow uniformity near the edge of the substrate result in deposition non-uniformity at the substrate perimeter, causing center-to-edge non-uniformity. However, the preheat ring 117 and the susceptor 106 of the present disclosure substantially reduce the above adverse effects. By supporting the preheat ring 117 on the susceptor 106 during processing, the leading rotating edge (e.g., an outer edge 245 of the preheat ring 117) exposed to process gas flow is effectively extended away from the outer perimeter of the substrate 102. Thus, even if “dragging” of the process gas does occur, the process gas flow non-uniformity is sufficiently distanced from the substrate 102 so as not to cause center-to-edge non-uniformity.

FIGS. 2C and 2D are schematic partial illustrations of a processing chamber configuration 200c, such as the processing chamber of FIG. 1, according to another embodiment. The processing chamber configuration 200c is similar to the processing chamber configuration 200a, and detailed descriptions of the same reference numerals are omitted for brevity. With reference to the processing chamber configuration 200c, the illustrated lower liner 163 lacks an insert 278. Rather, the lower liner 163 has a planar upper surface with the exception of the vertical extension 277. Exclusion of the insert 278 may be beneficial, for example, when the lower liner 163 and the preheat ring 117 are formed of the same or similar material, or otherwise have one more similar properties, such as heat transfer coefficients. In addition, omission of the insert 278 may facilitate reduced particle generation in the processing chamber, thus improving film quality.

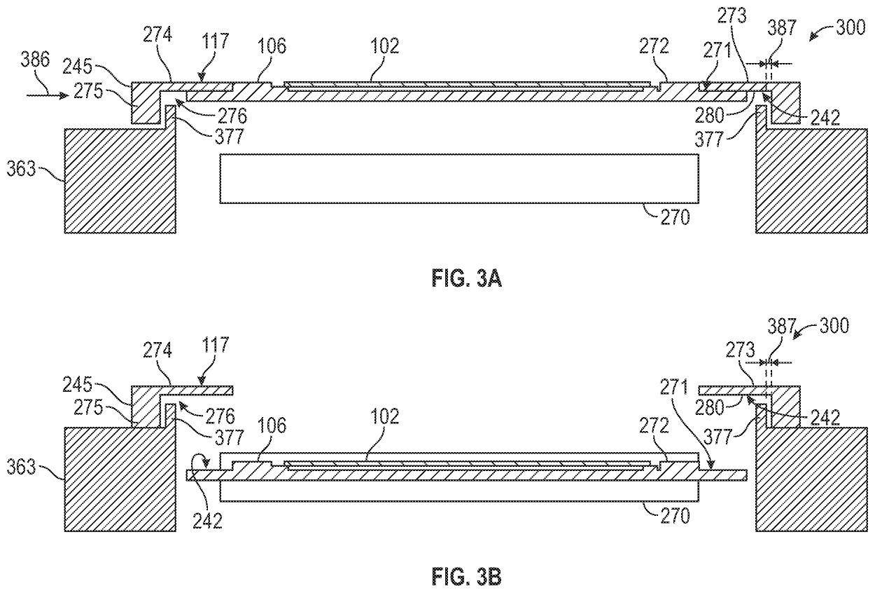

FIGS. 3A and 3B are schematic partial illustrations of a processing chamber configuration 300, such as of processing chamber 100, according to another embodiment. FIG. 3A illustrates the processing chamber configuration 300 in a processing position, while FIG. 3B illustrates the processing chamber configuration 300 in a loading/unloading position. The processing chamber configuration 300 is similar to the processing chamber configuration 200c, and descriptions of the same reference numerals are omitted for brevity.

The processing chamber configuration 300 utilizes a lower liner 363, rather than the lower liner 163 of processing chamber configuration 200c. The lower liner 363 includes a vertical extension 377 projecting from the upper surface of the lower liner 363. In one or more examples, the vertical extension 377 is a cylinder positioned at the radially inward edge of the lower liner 363. In one or more examples, the vertical extension 377 is a cylindrical sleeve. The vertical extension 377 creates a vertical overlap with the circular vertical extension 275 of the preheat ring 117 in the processing position. The vertical overlap reduces process gas flow 386 from gas flow inlet 114 (shown in FIG. 1) from traveling beneath the susceptor 106, thus reducing deposition of material in undesired areas of the process chamber. It is contemplated that the size of the vertical extension 377, and the lateral distance 387 between the circular vertical extension 275 of the preheat ring 117 and the vertical extension 377 may be selected to achieve predetermined flow characteristics on the back side of the susceptor 106. In one or more examples, the vertical extension 377 overlaps at least 25 percent (%) of the circular vertical extension 275 of the preheat ring 117, such as at least 50%, or at least 60%, or at least 70%, or at least 80% or at least 90%, during deposition.

FIGS. 3A and 3B illustrate one embodiment of a processing chamber configuration 300, however, other embodiments are also contemplated. For example, it is contemplated that the lower liner 363 may include an insert 278, such as that shown in processing chamber configuration 200a.

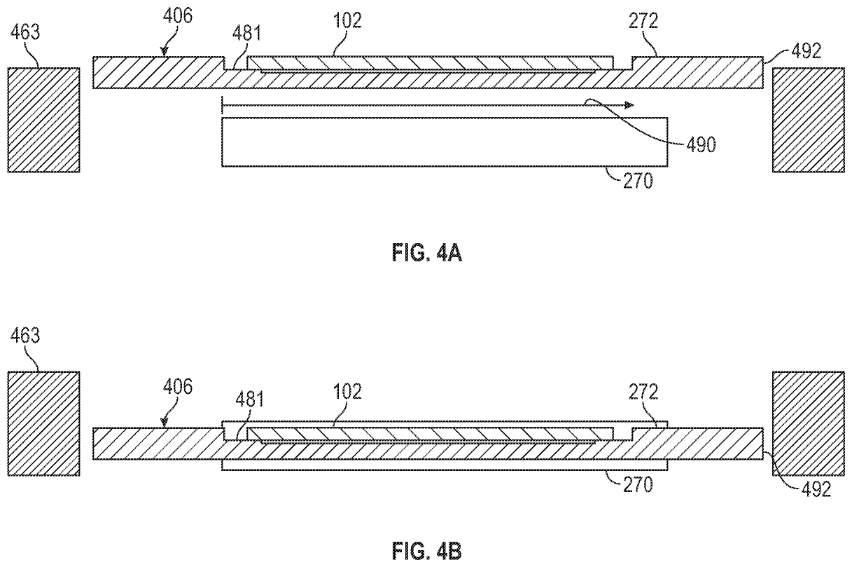

FIGS. 4A and 4B are schematic partial illustrations of a processing chamber configuration 400, such as of processing chamber 100, according to another embodiment. The processing configuration 400 is similar to the processing configuration 200c, and similar reference numerals have been omitted for brevity. However, the processing configuration 400 includes a susceptor 406 and a lower liner 463. The susceptor 406 includes a preheat ring integrally formed therewith or permanently attached thereto. Thus, the susceptor 406 has an increased outer diameter compared to other susceptors which support the same sized substrate 102. For example, the outer diameter 490 of the ledge 481 is about 40% to about 80 percent of the outer diameter of the susceptor 410, such as about 60% to about 70% of the outer diameter of the susceptor 410. This results in an outer edge 492 of the susceptor 406 being spaced from an outer edge of the substrate 102 by a sufficient distance (for example, greater than 50 mm, such as great than 60 mm, such as greater than 70 mm, such as greater than 80 mm, such as greater than 95 mm, such as greater than 105 mm, such as greater than 125 mm, such as greater than 140 mm, when processing a single 150 mm substrate within the outer diameter 490 of the ledge 481) to reduce process gas “drag” effects on the substrate 102. In one example, the outer edge 492 of the susceptor 406 is spaced from an outer edge of the ledge 481 by a distance that is 75% or more of the outer diameter 490 of the ledge 481, such as 80% or more of the outer diameter 490, such as 85% or more, 90% or more, or 95% or more of the outer diameter 490. In such a configuration, the surface area of the upper surface 472 is selected to provide sufficient distancing between the outer edge 492 and the substrate 102, and/or to provide sufficient surface area to preheat process gas as the process gas flows adjacent to the upper surface 472.

Because the susceptor 406 includes a preheat ring integrally formed therewith (or affixed thereto), the lower liner 463 has an inner diameter that is greater than an outer diameter of the susceptor 406. The inner diameter of the lower liner 463 allows the susceptor 406 to move between the processing position shown in FIG. 4A, and the loading/unloading position shown in FIG. 4B, without interference. The integral formation of the preheat ring with the susceptor 406 reduces particle contamination due to reduced contact with a lower liner, while still providing some or all of the benefits described above with respect to other embodiments.

Benefits of the present disclosure include reduced or eliminated deposition and/or contamination on unwanted locations of processing chambers, reduced or eliminated corrosion of chamber components, increased operational lifespans of chamber components, increased time between chamber cleanings, increased throughput, more uniform gas flow, and enhanced deposition uniformity (such as center-to-edge deposition uniformity).

It is contemplated that aspects described herein can be combined. For example, one or more features, aspects, components, operations, and/or properties of the processing chamber 100, the processing chamber configuration 200a, the processing chamber configuration 200c, the processing chamber configuration 300, and/or the processing chamber configuration 400 can be combined. It is further contemplated that any combination(s) can achieve the aforementioned benefits.

While the foregoing is directed to examples of the present disclosure, other and further examples of the disclosure may be devised without departing from the basic scope thereof, and the scope thereof is determined by the claims that follow.

What is claimed is:

1. A processing chamber, suitable for use in semiconductor processing, comprising:
a chamber body enclosing an interior volume;
a susceptor disposed in the interior volume, the interior volume including a purge volume below the susceptor and a process volume above the susceptor;
a liner disposed radially outward of the susceptor; and
a preheat ring, the preheat ring configured to engage the susceptor when the susceptor is an elevated processing position and to engage the liner when the susceptor is in a lowered loading/unloading position.

2. The processing chamber of claim 1, wherein an upper surface of the preheat ring and an upper surface of the susceptor are coplanar in the processing position.

3. The processing chamber of claim 1, wherein the liner comprises quartz.

4. The processing chamber of claim 3, wherein the liner comprises an insert disposed in an upper surface of the liner.

5. The processing chamber of claim 4, wherein the insert comprises silicon carbide.

6. The processing chamber of claim 1, wherein each of the susceptor and the preheat ring comprises one or more of silicon carbide, black quartz, graphite, or silicon carbide coated graphite.

7. The processing chamber of claim 1, wherein the liner includes a vertical extension protruding from an upper surface of the liner at a radially inward edge of the liner.

8. The processing chamber of claim 7, wherein the vertical extension overlaps with a circular vertical extension protruding from the lower surface of the preheat ring when the susceptor is in the processing position.

9. The processing chamber of claim 8, wherein the vertical extension overlaps at least 25 percent of the circular vertical extension 275 of the preheat ring 117 in the processing position.

10. The processing chamber of claim 8, wherein the circular vertical extension of the preheat ring is disposed outwardly of the vertical extension of the liner.

11. The processing chamber of claim 10, further comprising an insert disposed in a pocked formed in an upper surface of the liner, wherein the insert comprises silicon carbide, and the insert is disposed below the circular vertical extension of the preheat ring and outwardly of the vertical extension of the liner.

12. A method of processing a substrate, comprising:
positioning a substrate on a susceptor within a processing chamber;
vertically actuating the susceptor into contact with a preheat ring to disengage the preheat ring from a liner;
performing a deposition process on the substrate while the preheat ring is in contact with the susceptor; and
lowering the susceptor with the substrate thereon into a loading/unloading position, the lowering including engaging the liner with the preheat ring.

13. The method of claim 12, wherein the lowering further comprises disengaging the preheat ring from the susceptor.

14. The method of claim 12, wherein the deposition process comprises rotating the susceptor and the preheat ring while the preheat ring engages the susceptor.

15. The method of claim 12, wherein engaging the liner with the preheat ring comprises contacting an insert formed in an upper surface of the liner with the preheat ring.

16. The method of claim 15, wherein the liner comprises quartz, the insert comprises silicon carbide, and the preheat ring comprises silicon carbide.

17. A processing chamber, suitable for use in semiconductor processing, comprising:
a chamber body enclosing an interior volume;
a susceptor disposed in the interior volume, the interior volume including a purge volume below the susceptor and a process volume above the substrate support, the susceptor including a single pocket formed therein for supporting one substrate, the susceptor having an outer diameter that is at least 75% greater than the outer diameter of the pocket; and
a liner disposed radially outward of the susceptor.

18. The processing chamber of claim 17, wherein the susceptor is configured to move between a processing position and a loading/unloading position, and the susceptor remains clear of the liner in both the processing positon and the loading/unloading position.

19. The processing chamber of claim 18, wherein the susceptor has an outer diameter that is at least 80% greater than the outer diameter of the pocket.

20. The processing chamber of claim 18, wherein the susceptor has an outer diameter that is at least 85% greater than the outer diameter of the pocket.
